(19) United States
(12) Patent Application Publication
(10) Pub. No.: US 2025/0157968 A1
(43) Pub. Date: May 15, 2025

(54) SELF-HEALING SOLDER INTERCONNECTION

(71) Applicant: Meta Platforms, Inc., Menlo Park, CA (US)

(72) Inventors: Pradip Sairam PICHUMANI, Fremont, CA (US); Olga Vladimirovna BARYKINA-TASSA, San Mateo, CA (US)

(73) Assignee: Meta Platforms, Inc., Menlo Park, CA (US)

(21) Appl. No.: 18/932,045

(22) Filed: Oct. 30, 2024

Related U.S. Application Data
(60) Provisional application No. 63/597,580, filed on Nov. 9, 2023.

(51) Int. Cl. H01L 23/00

(52) U.S. Cl. CPC H01L 24/13; H01L 24/11; H01L 24/81; H01L 2224/11312; H01L 2224/1182; H01L 2224/11849; H01L 2224/13105; H01L 2224/13109; H01L 2224/13198; H01L 2224/13561; H01L 2224/13582; H01L 2224/13611; H01L 2224/13613; H01L 2224/13639; H01L 2224/13644; H01L 2224/13647; H01L 2224/13669; H01L 2224/81935

(57) ABSTRACT

Disclosed technology provides a solder ball including an outer layer having a first conductive material that is solid at an operating temperature of an electronic device, and an inner region having a second conductive material that flows at the operating temperature of the electronic device, wherein the inner region is surrounded by the outer layer. A method of manufacturing a solder ball includes forming an outer layer comprising a first conductive material that is solid at an operating temperature of an electronic device, wherein the outer layer surrounds an inner region, introducing a hole into the outer layer, injecting a second conductive material through the hole of the outer layer into the inner region, wherein the second conductive material flows at the operating temperature of the electronic device, and sealing the hole of the outer layer such that the second conductive material is retained within the inner region.

### CROSS-REFERENCE TO RELATED APPLICATIONS

The present application is a Non-Provisional patent application which claims the benefit of priority to U.S. Provisional Patent Application No. 63/597,580 filed on Nov. 9, 2023, which is incorporated by reference herein in its entirety.

### TECHNICAL FIELD

Embodiments generally relate to electronic devices. More particularly, embodiments relate to a self-healing solder interconnection for use in manufacturing electronic devices.

### BACKGROUND

Solder balls (also known as solder bumps) are used in manufacturing electronic devices to provide electrical interconnections between electronic components and metallic traces (typically copper) on a printed circuit board (PCB). Manufacturing processes use a reflow process with conventional choice of uniform alloy composition materials for the solder balls used to form the electrical interconnections. But the solder alloy becomes brittle over time, particularly in operating environments that can include significant heating and cooling cycles. Additionally, operating environments impart mechanical effects such as vibration and other motions on electronic components. Combined, thermomechanical stresses such as these produce permanent cracks and voiding in the solder interconnections that lead to signal integrity issues and, ultimately, electrical failure. For example, partial cracks in interconnections to high speed traces can result in signal integrity issues due to skin effect, and worsening cracks can result in signal loss. Voltage degradation due to cracks can also result in lowering of potential difference which can also affect signal integrity.

### SUMMARY OF PARTICULAR EXAMPLES

In some embodiments, a solder ball includes an outer layer comprising a first conductive material that is solid at an operating temperature of an electronic device, and an inner region comprising a second conductive material that flows at the operating temperature of the electronic device, wherein the inner region is surrounded by the outer layer.

In some embodiments, a method of manufacturing a solder ball includes forming an outer layer comprising a first conductive material that is solid at an operating temperature of an electronic device, wherein the outer layer surrounds an inner region, introducing a hole into the outer layer, injecting a second conductive material through the hole of the outer layer into the inner region, wherein the second conductive material flows at the operating temperature of the electronic device, and sealing the hole of the outer layer such that the second conductive material is retained within the inner region.

In some embodiments, a method of manufacturing an electronic device includes placing a plurality of solder balls, each at a respective contact point on a printed circuit board (PCB) of the electronic device, wherein each of the plurality of solder balls comprises an outer layer comprising a first conductive material that is solid at an operating temperature of the electronic device, and an inner region comprising a second conductive material that flows at the operating temperature of the electronic device, wherein the inner region is surrounded by the outer layer, placing a plurality of electronic components in position proximate to the PCB, wherein each electronic component is in contact with one or more of the solder balls, applying heat to the plurality of solder balls such that each outer layer melts in part to form an electrical bond with the respective contact point and with one of the electronic components, and allowing the outer layer of each solder ball to cool.

### BRIEF DESCRIPTION OF THE DRAWINGS

The various advantages of the embodiments will become apparent to one skilled in the art by reading the following specification and appended claims, and by referencing the following drawings, in which:

FIGS. 1A-1C illustrate examples of solder balls according to one or more embodiments;

FIGS. 2A-2B provide diagrams illustrating example techniques for manufacturing a solder ball according to one or more embodiments;

FIG. 3 provides a flow diagram illustrating an example method of manufacturing a solder ball according to one or more embodiments;

FIG. 4 provides a diagram illustrating an example technique for manufacturing a solder ball according to one or more embodiments;

FIG. 5 provides a flow diagram illustrating an example method of manufacturing a solder ball according to one or more embodiments;

FIGS. 6A-6C illustrate examples of solder balls with surround material according to one or more embodiments;

FIG. 7 provides a flow diagram illustrating an example method of manufacturing an electronic device according to one or more embodiments; and

FIGS. 8A-8C provide diagrams illustrating an example of a self-healing solder interconnection according to one or more embodiments.

### DESCRIPTION OF EMBODIMENTS

An improved solder ball technology as described herein provides self-healing solder interconnections for use in manufacturing electronic devices. The technology helps improve the overall performance of electronic devices over time by self-healing cracks in solder interconnections caused, e.g., by thermomechanical stresses such as heating and cooling cycles, vibration and other motions on electronic components, and other thermomechanical stress events.

In accordance with embodiments, solder balls used for forming electrical interconnections in an electronic device (e.g., PCB with one or more electronic components) include a hard outer conductive (e.g., metallic) layer, or “shell,” that surrounds a soft conductive (e.g., metallic) inner region, or “yolk.” The soft inner region comprises a material (e.g., metallic material) that flows at operating temperatures—such that when a crack forms in the outer “shell” the soft “yolk” flows (e.g., bleeds through) into the crack to maintain electrical connectivity through the solder ball and its connection points. Selection of materials for each component is dependent on several factors, including, e.g., the boundary thickness required during alloying, attainment of boundary stability, stability at operating temperatures, etc. For example, material for the “yolk” should be sufficiently soft/fluid at operating temperatures such that the material flows, allowing the “yolk” material to “bleed through” during the formation of cracks in the outer “shell.” Depending on the nature of the “yolk” material used, the “yolk” can be either flowing, or solid, or semi-solid (e.g., gel-like) at temperatures that are cooler than operating temperatures (e.g., during manufacture of the solder ball itself).

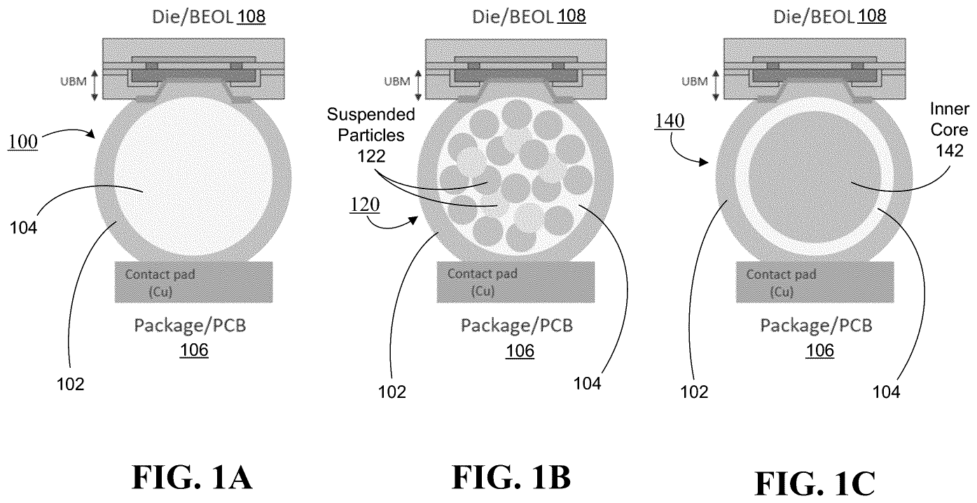

FIGS. 1A-1C illustrate examples of solder balls according to one or more embodiments, with reference to components and features described herein including but not limited to the figures and associated description. In each of the examples as illustrated in FIGS. 1A-1C, the example solder ball is shown to be arranged between a contact pad (e.g., copper) of a package/PCB 106 and a die/backend of the line (BEOL) 108 of an electronic component. The package/PCB with electronic component(s) forms an electronic device (or a part thereof). In each example, the solder ball includes an outer layer comprising a first conductive material that is solid (e.g., a hard “shell”) at an operating temperature of the electronic device, and an inner region comprising a second conductive material that flows (e.g., a soft “yolk”) at the operating temperature of the electronic device, where the inner region is surrounded by the outer layer (e.g., the soft “yolk” is disposed inside the hard “shell”).

Turning to FIG. 1A, a first example solder ball 100 is illustrated. The solder ball 100 includes an outer layer 102 (e.g., hard “shell”) having a first conductive material that is solid at an operating temperature of the electronic device. The solder ball 100 further includes an inner region 104 (e.g., soft “yolk”) having a second conductive material that flows at the operating temperature of the electronic device, where the inner region 104 is surrounded by the outer layer 102. In the example of FIG. 1A, the inner region 104 has a uniform material that occupies the entire interior portion of the solder ball—e.g., the portion inside of the outer layer 102. As illustrated, the solder ball 100 is positioned between a package/PCB 106 and a die/BEOL 108 for use in manufacturing an electronic device.

In embodiments, examples of conductive materials used for the outer layer 102 (e.g., the hard “shell”) includes one or more metals such as, e.g., silver, tin, gold, copper, platinum or bismuth—including alloys thereof (such as, e.g., a tin/silver alloy). In embodiments, examples of conductive materials for the inner region 104 (e.g., the soft “yolk”) includes one or more metals such as, e.g., indium, gallium—including alloys thereof.

In embodiments, material selections for the outer layer 102 (e.g., hard “shell”) and the inner region 104 (e.g., soft “yolk”) take into consideration the coefficient of thermal expansion (CTE) of the respective materials. For example, in embodiments the material for the inner region 104 is selected to have a CTE that reduces a differential with the CTE of the outer layer 102. A benefit of reducing a differential between the CTE of the outer layer and the CTE of the inner region is such that at operating temperatures there is not an undue pressure created on the outer layer 102 from the inner region 104 that might create stresses on the outer layer 102. In some embodiments, reducing a differential between the CTE of the inner region 104 and the CTE of the outer layer 102 includes reducing the differential below a threshold (e.g., a percentage threshold). As one example, the material of the inner region 104 is selected such that a CTE of the inner region 104 is within fifty (50) percent of the CTE of the outer layer 102.

Turning now to FIG. 1B, a second example solder ball 120 is illustrated. The solder ball 120 is similar to the solder ball 100 (FIG. 1A), but the inner region 104 includes a plurality of suspended particles 122 that are suspended in the second conductive material (e.g., forming a “yolk” mixture). In embodiments, the suspended particles are of a number and material selected to adjust the CTE of the inner region 104 (e.g., the “yolk” mixture) to meet desired design criteria (such as, e.g., reducing a differential between the CTE of the outer layer 102 and the CTE of the inner region 104) and/or to reduce the volume of the second conductive material (“yolk”) used. In some embodiments, the suspended particles are each made of a common (e.g., same) material, while in other embodiments at least some of the suspended particles are made of different materials (e.g., to better control the CTE of the “yolk” mixture). As illustrated, the solder ball 100 is positioned between a package/PCB 106 and a die/BEOL 108 for use in manufacturing an electronic device. The suspended particles 122 are typically conductive (e.g., metallic) to promote good electrical connection between the electrical component and the contact pad of the PCB.

In embodiments, examples of conductive materials used for the suspended particles 122 includes one or more metals such as, e.g., silver, tin, gold, copper, platinum or bismuth—including alloys thereof (such as, e.g., a tin/silver alloy). The material used for the suspended particles 122 does not have to be the same as the material used in the outer layer 102.

Turning now to FIG. 1C, a third example solder ball 140 is illustrated. The solder ball 140 is similar to the solder ball 100 (FIG. 1A), but the inner region 104 includes an inner core 142 within the second conductive material (e.g., forming a “yolk” mixture), where the inner core 142 is located in approximately the center of the solder ball 140. The inner core 142 is of a size and material selected to adjust the CTE of the inner region 104 (e.g., the “yolk” mixture) to meet desired design criteria (such as, e.g., reducing a differential between the CTE of the outer layer 102 and the CTE of the inner region 102) and/or to reduce the volume of the second conductive material (“yolk”) used. As illustrated, the solder ball 100 is positioned between a package/PCB 106 and a die/BEOL 108 for use in manufacturing an electronic device. The inner core 142 is typically conductive (e.g., metallic) to promote good electrical connection between the electrical component and the contact pad of the PCB.

In embodiments, examples of conductive materials used for the inner core 142 includes one or more metals such as, e.g., silver, tin, gold, copper, platinum or bismuth—including alloys thereof (such as, e.g., a tin/silver alloy). The material used for the inner core 142 does not have to be the same as the material of the outer layer 102.

In each of the examples of FIGS. 1A-1C, the die/BEOL 108 includes under bump metallurgy (UBM) for providing an electrical connection to a contact pad of the package PCB 106 via the solder ball. Through the manufacturing process, the solder ball is temporarily subjected to heat sufficient to melt a portion of the outer layer 102 to form an electrical bond with the UBM of the die/BEOL 108 and with the contact pad of the package/PCB 106. In embodiments, the solder ball 100 (or the solder ball 120 or the solder ball 140) is sized according to desired criteria, including, for example, matching (approximately) the desired height of UBMs of electronic components above the PCB. While an electronic component with die/BEOL 108 is illustrated in FIGS. 1A-1C, the solder balls as described herein can be used with any solderable electronic component.

The manufacturing process for an electronic device (e.g., including a PCB 106 and one or more electronic components having a die/BEOL 108) is the same as or similar to conventional manufacturing processes for using a conventional solder ball to form an electrical bond with the UBM of the die/BEOL 108 and with the contact pad of the package/PCB 106. For example, one or more solder balls (e.g., solder ball(s) 100, solder ball(s) 120 and/or solder ball(s) 140)) are placed at contact pad locations on the PCB 106—e.g., using conventional “ball attach” processes for solder ball placement. Then the electronic component(s) are placed on the PCB 106, and heat is applied to melt a portion of the outer layer 102 (e.g., hard “shell”) to form the desired electrical bonds. Thus, the material for the outer layer 102 must have a melting point to permit melting at temperatures used during the device manufacturing process but revert to solid form at operating temperatures for the electronic device.

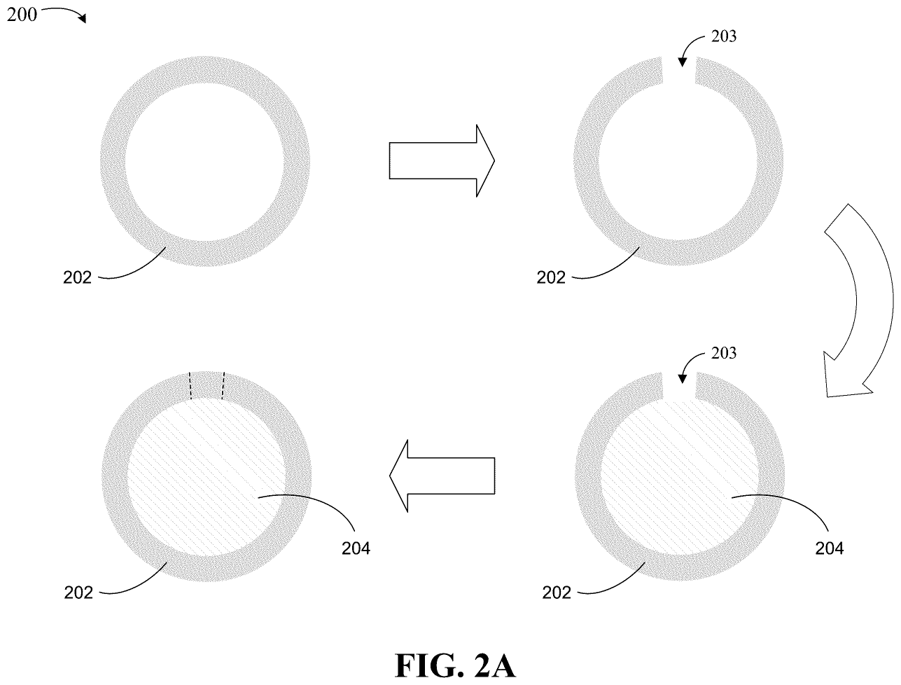

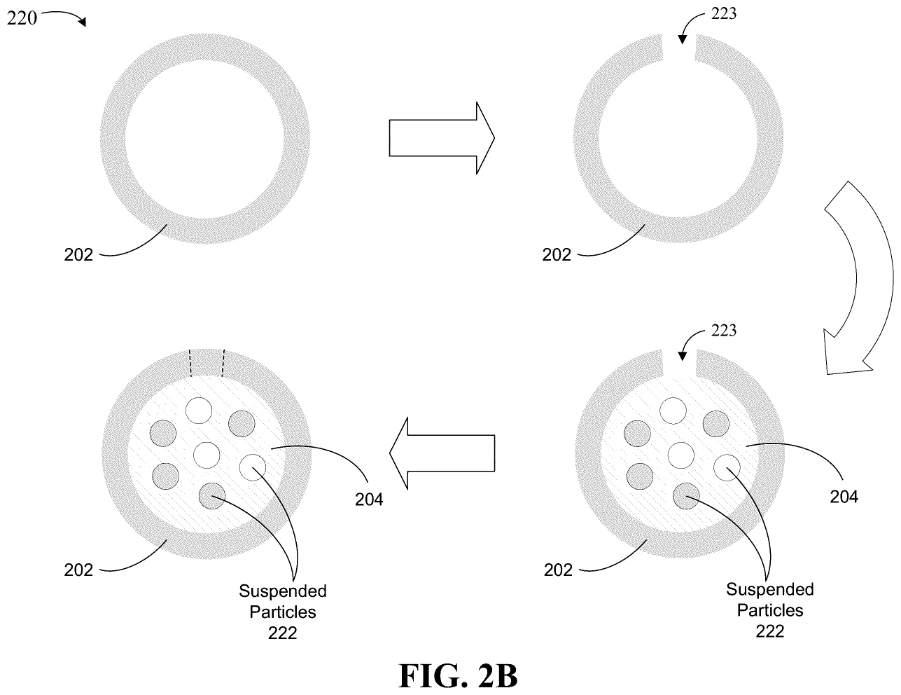

FIGS. 2A-2B provide diagrams illustrating example techniques (processes) for manufacturing a solder ball according to one or more embodiments, with reference to components and features described herein including but not limited to the figures and associated description. Turning to FIG. 2A, a first example manufacturing technique (process) 200 is illustrated for manufacturing a solder ball (such as, e.g., the solder ball 100 in FIG. 1A) for later use in manufacturing an electronic device. As shown in FIG. 2A, an outer layer 202 (e.g., hard “shell”) is created using the first conductive material, with a desired size and thickness. In embodiments, the outer layer 202 corresponds to the outer layer 102 and the inner region 204 corresponds to the inner region 104 of the solder ball 100 in FIG. 1A (already discussed).

A hole 203 (e.g., a small hole) is introduced in the outer layer 202. The hole 203 is introduced—e.g., via drilling or puncture, etc. —either during formation of the outer layer 202 or afterward. Next, the second conductive material (“yolk”) is injected into the inner region 204 of the solder ball via the hole 203, and then the hole 203 is sealed (e.g., with a small plug or other sealing technique) to retain the second conductive material within the inner region 204. In embodiments the hole 203 is sized to permit a device (e.g., injection nozzle) to fit in the hole in order to inject the second conductive material into the inner region 204. In embodiments the process 200 is used for solder balls with a uniform “yolk” (e.g., the solder ball 100 as illustrated in FIG. 1A).

Turning now to FIG. 2B, a second example manufacturing technique (process) 220 is illustrated, for manufacturing a solder ball (such as, e.g., the solder ball 120 in FIG. 1B) for later use in manufacturing an electronic device. The manufacturing technique 220 is similar to the manufacturing technique 200 (FIG. 2A). As shown in FIG. 2B, an outer layer 202 (e.g., hard “shell”) is created using the first conductive material, with a desired size and thickness. In embodiments, the outer layer 202 corresponds to the outer layer 102 and the inner region 204 corresponds to the inner region 104 of the solder ball 120 in FIG. 1B (already discussed).

A hole 223 (e.g., a small hole) is introduced in the outer layer 202. The hole 223 is introduced—e.g., via drilling or puncture, etc. —either during formation of the outer layer 202 or afterward. Next, the second conductive material with suspended particles 222 (e.g., “yolk” mixture) is injected into the inner region 204 of the solder ball via the hole 223, and then the hole 223 is sealed (e.g., with a small plug or other sealing technique) to retain the second conductive material within the inner region 204. In embodiments the hole 223 is sized to permit a device (e.g., injection nozzle) to fit in the hole in order to inject the second conductive material with suspended particles 222 into the inner region 204. Alternatively, in some embodiments the hole 223 is sized to permit introduction of the suspended particles 222 into the inner region 204 after the second conductive material (.e.g., without suspended particles) has been injected into the inner region 204. In embodiments the process 220 is used for solder balls with a “yolk” mixture having suspended particles (e.g., the solder ball 120 as illustrated in FIG. 1B).

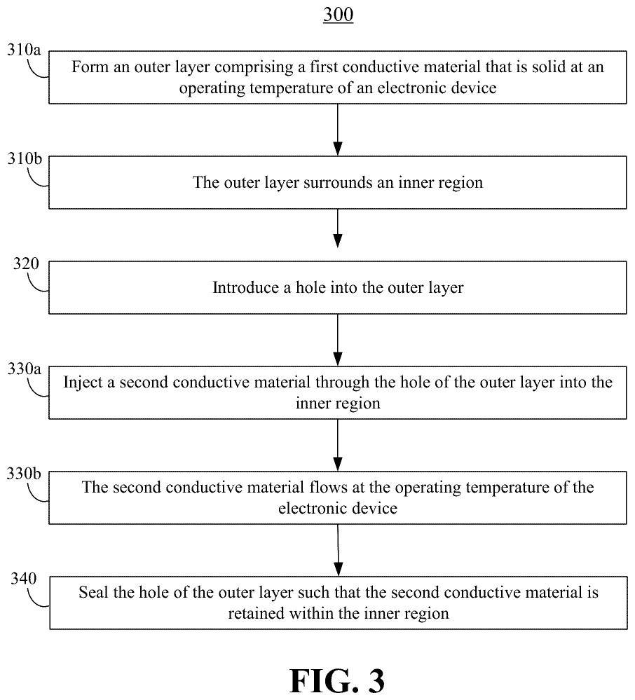

FIG. 3 provides a flow diagram illustrating an example method 300 of manufacturing a solder ball according to one or more embodiments, with reference to components and features described herein including but not limited to the figures and associated description. In embodiments, the method 300 corresponds to the process 200 (FIG. 2A, already discussed) and/or to the process 220 (FIG. 2B, already discussed), and/or to aspects thereof. Block 310a provides for forming an outer layer comprising a first conductive material that is solid at an operating temperature of an electronic device, where at block 310b the outer layer surrounds an inner region. Block 320 provides for introducing a hole into the outer layer. Block 330a provides for injecting a second conductive material through the hole of the outer layer into the inner region, where at block 330b the second conductive material flows at the operating temperature of the electronic device. Block 340 provides for sealing the hole of the outer layer such that the second conductive material is retained within the inner region.

In embodiments, the second conductive material is to flow into a crack in the outer layer. In some embodiments, the first conductive material includes one or more of silver, tin, gold, copper, platinum, or bismuth; thus, the first conductive material can include an alloy of any one or more of the foregoing metals. In some embodiments, the second conductive material includes one or more of indium or gallium; thus, the second conductive material can include an alloy of indium and/or gallium. In some embodiments, the first conductive material has a first coefficient of thermal expansion (CTE), and the second conductive material is selected based on reducing a differential between a second CTE of the second conductive material and the first CTE.

In some embodiments, the inner region further includes a plurality of suspended particles in the second conductive material. In some embodiments, the first conductive material has a first coefficient of thermal expansion (CTE), and a number and material of the plurality of suspended particles is selected based on reducing a differential between a second CTE of the second conductive material and the first CTE.

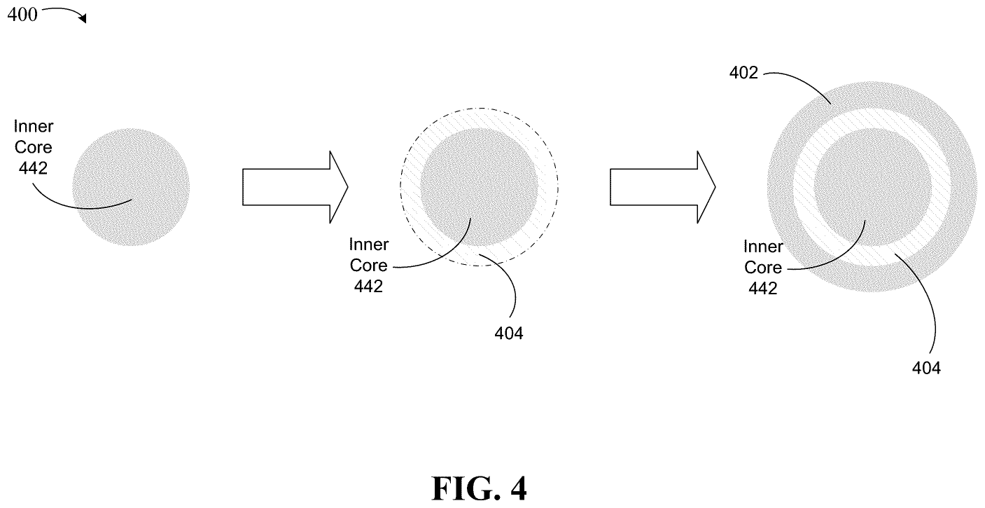

FIG. 4 provides a diagram illustrating an example technique (process) 400 for manufacturing a solder ball according to one or more embodiments, with reference to components and features described herein including but not limited to the figures and associated description. The example technique 400 is, in embodiments, used to manufacture a solder ball (such as, e.g., the solder ball 140 in FIG. 1CA) for later use in manufacturing an electronic device. As shown in FIG. 4, an inner core 442 (e.g., a conductive material) is formed as a solid, and a second conductive material (e.g., soft “yolk”) is disposed around the inner core 442 forming an inner region 404. As one example, the inner core 442 is dipped into the “yolk” which is then permitted to become hardened (e.g., by bringing to a cooler temperature), forming a hardened “yolk”/core assembly for the inner region 404. Then an outer layer 402 is formed as an outer coating/layer on top of the inner region 404 (e.g., a hardened “yolk”/core assembly). In embodiments, the outer layer 402 corresponds to the outer layer 102 and the inner region 404 corresponds to the inner region 104 of the solder ball 140 in FIG. 1C (e.g., the inner core 442 corresponds to the inner core 142).

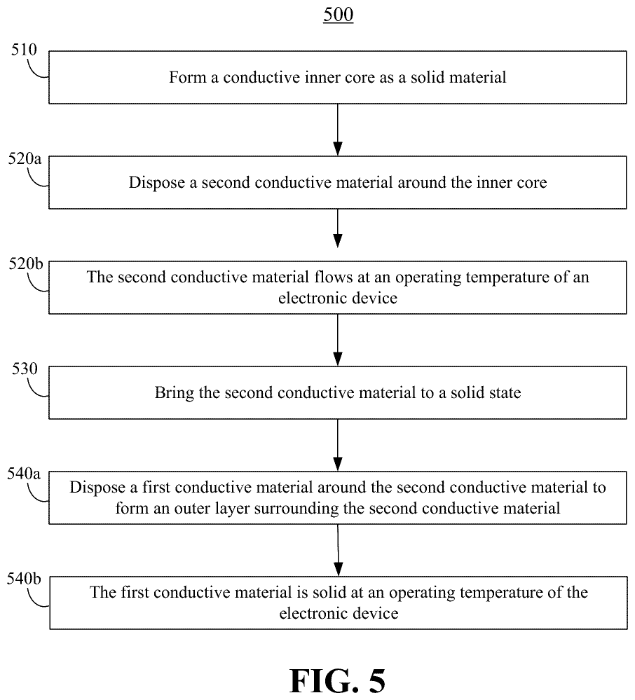

FIG. 5 provides a flow diagram illustrating an example method 500 of manufacturing a solder ball according to one or more embodiments, with reference to components and features described herein including but not limited to the figures and associated description. In embodiments, the method 500 corresponds to the process 400 (FIG. 4, already discussed) and/or to aspects thereof. Block 510 provides for forming a conductive inner core as a solid material. Block 520a provides for disposing a second conductive material around the inner core, where at block 520b the second conductive material flows at an operating temperature of an electronic device. Block 530 provides for bringing the second conductive material to a solid state. Block 540a provides for and disposing a third conductive material around the second conductive material to form an outer layer surrounding the second conductive material, where at block 540b the third conductive material is solid at an operating temperature of the electronic device.

In embodiments, the second conductive material is to flow into a crack in the outer layer. In some embodiments, the third conductive material comprises one or more of silver, tin, gold, copper, platinum, or bismuth; thus, the third conductive material can include an alloy of any one or more of the foregoing metals. In some embodiments, the second conductive material comprises one or more of indium or gallium; thus, the second conductive material can include an alloy of indium and/or gallium. In some embodiments, the third conductive material has a first coefficient of thermal expansion (CTE), and the second conductive material is selected based on reducing a differential between a second CTE of the second conductive material and the first CTE. In some embodiments, the third conductive material has a first coefficient of thermal expansion (CTE), and a size and material of the conductive inner core is selected based on reducing a differential between a second CTE of the second conductive material and the first CTE.

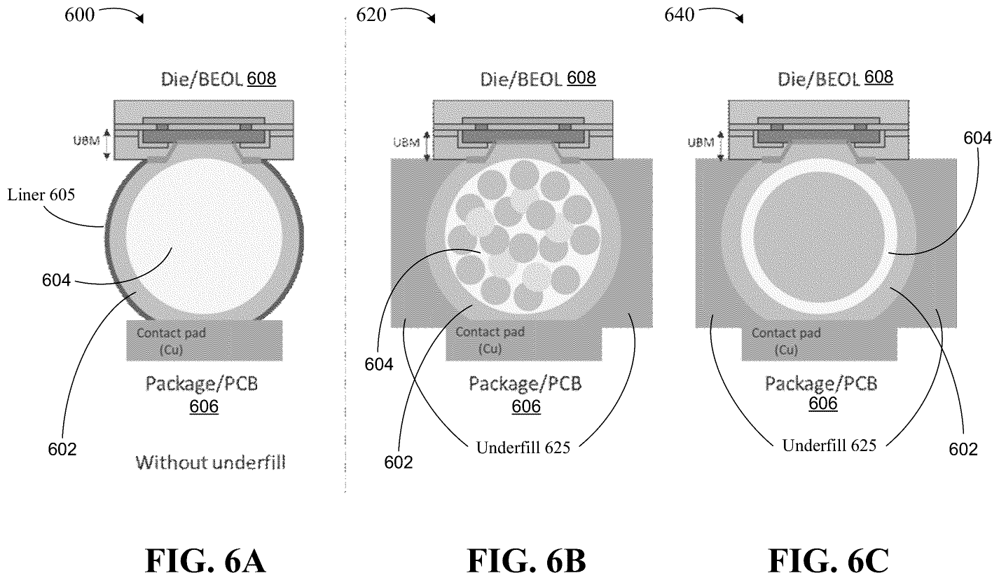

FIGS. 6A-6C illustrate examples of solder balls with surround material according to one or more embodiments, with reference to components and features described herein including but not limited to the figures and associated description. In each of the examples as illustrated in FIGS. 6A-6C, the example solder ball is shown to be arranged between a contact pad (e.g., copper) of a package/PCB 606 and a die/backend of the line (BEOL) 608 of an electronic component. The package/PCB with electronic component(s) forms an electronic device (or a part thereof). The surround material shown in FIGS. 6A-6C is non-conductive and serves as a barrier to keep the second conductive material (e.g., “yolk”) within the footprint of the solder ball itself, to prevent the second conductive material from bleeding outside of the solder ball when cracks form in the outer layer.

Turning to FIG. 6A, an example electronic device 600 is illustrated with a solder ball and surround material that is an expandable liner 605 (e.g., coating). The liner 605 is formed on the outside of the exposed portion of the solder ball (e.g., after the electrical bonds have been formed with the die/BEOL 608 and the contact pad of the package/PCB 606). The liner 605 is a non-conducting (insulating) material (e.g., a polymer), and is selected with sufficient elasticity to remain in place as a non conductor/insulator at operating temperatures. The solder ball includes an outer layer 602 (e.g., hard “shell”) having a first conductive material that is solid at an operating temperature of the electronic device, and. an inner region 604 (e.g., soft “yolk”) having a second conductive material that flows at the operating temperature of the electronic device, where the inner region 604 is surrounded by the outer layer 602; in embodiments the solder ball illustrated in FIG. 6A corresponds to the solder ball 100 (FIG. 1A). While the example of FIG. 6A illustrates a liner 605 used with an example of a solder ball (e.g. the solder ball 100 in FIG. 1A), in embodiments the liner 605 is also used with the example solder ball 120 (FIG. 1B, already discussed) and/or the example solder ball 140 (FIG. 1C, already discussed). In some embodiments, the electronic device 600 has a liner 605 without underfill (as illustrated in the example of FIG. 6A), but in other embodiments underfill is applied after the liner 605 is formed.

Turning now to FIG. 6B, an example electronic device 620 is illustrated with a solder ball and surround material that is an underfill material 625. The underfill material 625 is used to fill spacing between the die/BEOL 608 and the package/PCB 606. The underfill material 625 is a non-conducting (insulating) material, and in some embodiments is selected based on CTE considerations. The solder ball in FIG. 6B includes an outer layer 602 (e.g., hard “shell”) having a first conductive material that is solid at an operating temperature of the electronic device, and an inner region 604 (e.g., soft “yolk”) having a second conductive material that flows at the operating temperature of the electronic device along with suspended particles (such as the suspended particles 122 in FIG. 1B), where the inner region 604 is surrounded by the outer layer 602. In embodiments the solder ball illustrated in FIG. 6B corresponds to the solder all 120 (FIG. 1B). While the example of FIG. 6B illustrates underfill 625 used with an example of a solder ball (e.g. the solder ball 120 in FIG. 1B), in embodiments the underfill is also used with the solder ball 100 (FIG. 1A, already discussed) and/or the solder ball 140 (FIG. 1C), as shown in FIG. 6C.

Turning now to FIG. 6C, an example electronic device 640 is illustrated with a solder ball and surround material that is an underfill material 625. The electronic device 640 of FIG. 6C is similar to the electronic device 620 of FIG. 6B, with the exception that the solder ball in FIG. 6C (such as, e.g., the solder ball 140 in FIG. 1C) includes an inner core (such as the inner core 142 in FIG. 1C), instead of suspended particles (as in FIGS. 1B/6B).

In embodiments the underfill material 625 in FIGS. 6B and/or 6C is the same as typically used in conventional PCB manufacturing processes (e.g., for cushioning and/or insulating), such as an epoxy and/or other filler material. When underfill material 625 is used such as illustrated in FIGS. 6B and 6C, a liner (such as, e.g., the liner 605 shown in FIG. 6A) is typically not required, but in some embodiments a liner (such as liner 605) can be applied before the underfill material 625 is placed.

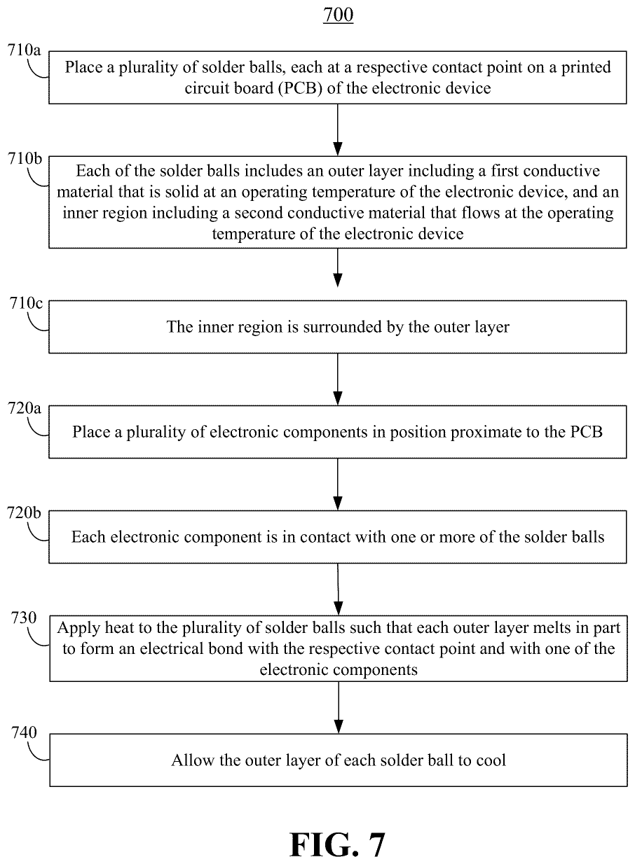

FIG. 7 provides a flow diagram illustrating an example method of manufacturing an electronic device according to one or more embodiments, with reference to components and features described herein including but not limited to the figures and associated description. In embodiments, the electronic device includes a package/PCB (such as, e.g., a package/PCB 106 as shown in FIGS. 1A/6A) and one or more electronic components (such as, e.g., a die/BEOL 108 of an electronic component as shown in FIGS. 1A/6A). Block 710a provides for placing a plurality of solder balls, each at a respective contact point on a printed circuit board (PCB) of the electronic device, where each of the plurality of solder balls comprises an outer layer comprising a first conductive material that is solid at an operating temperature of the electronic device, and an inner region comprising a second conductive material that flows at the operating temperature of the electronic device (block 710b) and the inner region is surrounded by the outer layer (block 710c). Block 720a provides for placing a plurality of electronic components in position proximate to the PCB, where at block 720b each electronic component is in contact with one or more of the solder balls. Block 730 provides for applying heat to the plurality of solder balls such that each outer layer melts in part to form an electrical bond with the respective contact point and with one of the electronic components. Block 740 provides for allowing the outer layer of each solder ball to cool. Cooling allows a solder ball to achieve a mechanical bond with the respective contact point or electronic component.

In embodiments, the second conductive material is to flow into a crack in the outer layer. In some embodiments, the first conductive material includes one or more of silver, tin, gold, copper, platinum, or bismuth; thus, the first conductive material can include an alloy of any one or more of the foregoing metals. In some embodiments, the second conductive material includes one or more of indium or gallium; thus, the second conductive material can include an alloy of indium and/or gallium. In some embodiments, the first conductive material has a first coefficient of thermal expansion (CTE), and the second conductive material is selected based on reducing a differential between a second CTE of the second conductive material and the first CTE.

In some embodiments, the inner region further includes a plurality of suspended particles in the second conductive material. In some embodiments, the first conductive material has a first coefficient of thermal expansion (CTE), and a number and material of the plurality of suspended particles is selected based on reducing a differential between a second CTE of the second conductive material and the first CTE.

In some embodiments, the inner region further includes a metallic core surrounded by the second conductive material. In some embodiments, the first conductive material has a first coefficient of thermal expansion (CTE), and a size and material of the metallic core is selected based on reducing a differential between a second CTE of the second conductive material and the first CTE.

In some embodiments, the method further includes after allowing the outer layer of each solder ball to cool, applying an outer coating to each of the solder balls such that for each solder ball the outer coating covers any exposed area of the solder ball, wherein the outer coating comprises a non-conductive liner. In some embodiments, the method further includes after allowing the outer layer of each solder ball to cool, applying a non-conductive underfill material between each of the electronic components and the PCB such that the underfill covers any exposed area of each solder ball.

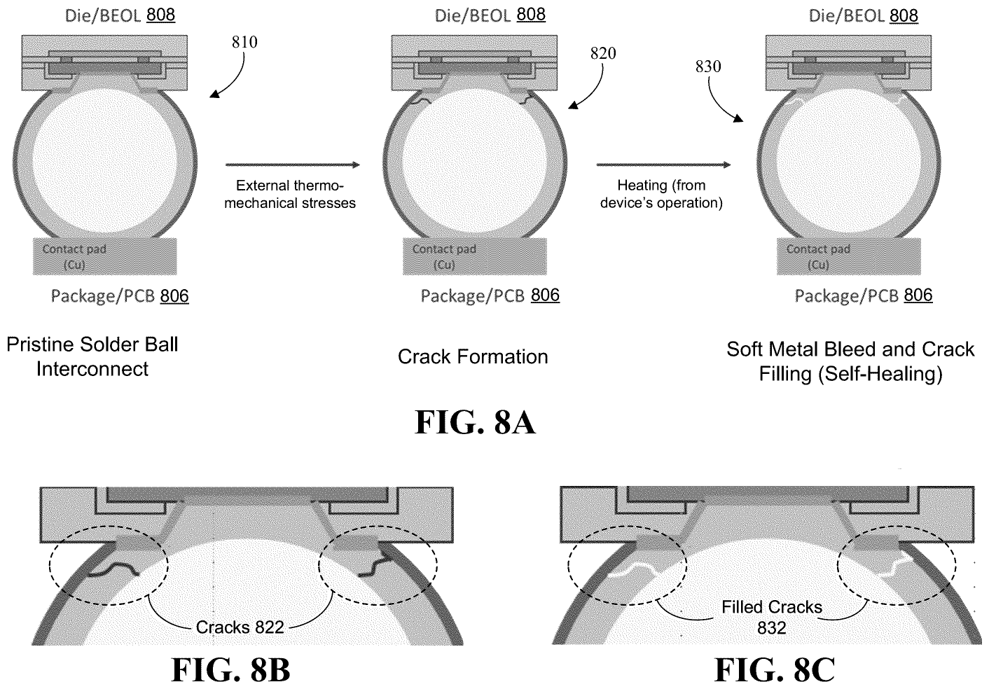

FIGS. 8A-8C provide diagrams illustrating an example of a self-healing solder interconnection according to one or more embodiments, with reference to components and features described herein including but not limited to the figures and associated description. Turning to FIG. 8A, the figure illustrates a scenario of an electronic device having a solder ball (e.g., as described herein with reference to FIGS. 1A-1C, 2A-2B, 3, 4, 5, 6A-6C and/or 7) having three stages 810, 820 and 830. The stages 810, 820 and 830 illustrate an example solder ball as positioned in an electronic device between and interconnected to a package/PCB 806 and a die/BEOL 808 of an electronic component. As illustrated in FIG. 8A, there is an outer liner surrounding exposed portions of the solder ball (such as, e.g., the liner 605 as described herein with reference to FIG. 6A). At stage 810, the solder ball is pristine and there are no defects in the solder ball or in the interconnections. For example, the stage 810 can exist shortly after manufacture of the subject electronic device.

During operation of the electronic device, the solder ball with interconnections can be subjected to thermomechanical stresses. In embodiments, the thermomechanical stresses include one or more of thermal shock, thermal expansion/contraction, vibration, twisting, other thermal or mechanical stresses, etc. As a result, cracks can occur. In stage 820 of FIG. 8A, illustrated are cracks that have appeared in the outer layer (e.g., “shell”) of the solder ball due to the thermomechanical stresses (e.g., as can occur over time). FIG. 8B shows an enlargement of the region of the solder ball where the cracks 822 have appeared. The cracks 822 are illustrated as occurring in regions that are more susceptible to damage (e.g., near corners), but the cracks can appear anywhere in the outer layer.

When cracks occur in the solder ball and/or interconnections with the solder ball (e.g., as shown for stage 820), the self-healing function of the technology described herein provides for filling the cracks with the second conductive material (e.g., “yolk”) from the inner region of the solder ball. In stage 830 of FIG. 8A, the second conductive material (e.g., “yolk”) of the inner region of the example solder ball has flowed into the cracks, filling the cracks and thus repairing all or most of the damaged area. FIG. 8C shows an enlargement of the region of the solder ball where the second conductive material has flowed (e.g. “bleeds”) into the cracks 822 to fill the cracks—providing filled cracks 832. This occurs during operation of the electronic device, where in embodiments the second conductive material (e.g., “yolk”) of the inner region flows into the cracks 822, since the second conductive material flows at the device operating temperature—e.g., via heating from the device operation. In embodiments, depending on the material selected for the second conductive material, the second conductive material can flow at approximately 30 degrees centigrade or higher (e.g. for gallium) or approximately 110 degrees centigrade or higher (e.g. for indium).

While FIGS. 8A-8C illustrate the solder ball with a liner (e.g., the liner 605 in FIG. 6A) as surround material for some embodiments, in some embodiments underfill (e.g., the underfill material 625 in FIGS. 6B-6C) is used as surround material instead of a liner. When used in the electronic device, the surround material (e.g., liner and/or underfill material) surrounding exposed areas of the solder ball serves as a barrier to keep the second conductive material (e.g., “yolk”) within the footprint of the solder ball itself, to prevent the second conductive material from bleeding outside of the solder ball when cracks form in the outer layer.

By filling the cracks with the second conductive material, the thickness of the conductive material in the outer layer is maintained and electrical connectivity is supported, thus avoiding or minimizing signal degradation or loss. Thus, the solder technology described herein provides for self-healing of any formed voids, cracks, etc. which can otherwise lead to lost or degraded electrical connections, resulting in improved durability and reliability for electronic devices and increased lifetimes thereof.

As described above, the second conductive material (e.g., “yolk”) is fluid or flowing at device operating temperatures such that the second conductive material flows into cracks that can occur in the outer layer due to thermomechanical stresses. In some embodiments, for operating temperatures in the range of/exceeding 30° C. (86° F.), a second conductive material (“yolk”) including gallium (e.g., a gallium alloy) is used such that the second conductive material is fluid at such operating temperatures. In some other embodiments, for operating temperatures in the range of/exceeding 110° C. (230° F.), a second conductive material (“yolk”) including indium (e.g., an indium alloy) is used such that the second conductive material is fluid or flowing at such operating temperatures.

The solder balls and manufacturing technologies described herein can be employed in any number of applications. For example, the solder balls and manufacturing technologies can be used for manufacturing virtually any type of electronic devices requiring soldered electronic components, including computerized devices, and especially devices that are more vulnerable to cracking. Enhanced electronic devices made using the solder ball technology described herein can be employed in many different operating environments, including those providing high thermomechanical stresses. For example, such enhanced devices can be employed in high performance environments (such as, e.g., data centers), thermally harsh environments (e.g., freezers), and other challenging environments, etc.

### ADDITIONAL NOTES AND EXAMPLES

Example A1 includes a solder ball comprising an outer layer comprising a first conductive material that is solid at an operating temperature of an electronic device, and an inner region comprising a second conductive material that flows at the operating temperature of the electronic device, wherein the inner region is surrounded by the outer layer.

Example A2 includes the solder ball of Example A1, wherein the first conductive material comprises one or more of silver, tin, gold, copper, platinum, or bismuth.

Example A3 includes the solder ball of Example A1 or A2, wherein the second conductive material comprises one or more of indium or gallium.

Example A4 includes the solder ball of any of Examples A1-A3, wherein the first conductive material has a first coefficient of thermal expansion (CTE), and wherein the second conductive material is selected based on reducing a differential between a second CTE of the second conductive material and the first CTE.

Example A5 includes the solder ball of any of Examples A1-A4, wherein the inner region further includes a plurality of suspended particles in the second conductive material.

Example A6 includes the solder ball of Example A5, wherein the first conductive material has a first coefficient of thermal expansion (CTE), and wherein a number and material of the plurality of suspended particles is selected based on reducing a differential between a second CTE of the second conductive material particles and the first CTE.

Example A7 includes the solder ball of any of Examples A1-A4, wherein the inner region further includes a metallic core surrounded by the second conductive material.

Example A8 includes the solder ball of Example A7, wherein the first conductive material has a first coefficient of thermal expansion (CTE), and wherein a size and material of the metallic core is selected based on reducing a differential between a second CTE of the second conductive material and the first CTE.

Example A9 includes the solder ball of any of Examples A1-A8, wherein the second conductive material is to flow into a crack in the outer layer.

Example D1 includes an electronic device comprising a printed circuit board (PCB) having a plurality of contact points and a plurality of electronic components, wherein each of the plurality of electronic components is electrically bonded to one or more of the contact points via one or more respective solder balls, wherein each solder ball comprises an outer layer comprising a first conductive material that is solid at an operating temperature of the electronic device, and an inner region comprising a second conductive material that flows at the operating temperature of the electronic device, wherein the inner region is surrounded by the outer layer.

Example D2 includes the electronic device of Example D1, wherein the first conductive material comprises one or more of silver, tin, gold, copper, platinum, or bismuth.

Example D3 includes the electronic device of Example D1 or D2, wherein the second conductive material comprises one or more of indium or gallium.

Example D4 includes the electronic device of any of Examples D1-D3, wherein the first conductive material has a first coefficient of thermal expansion (CTE), and wherein the second conductive material is selected based on reducing a differential between a second CTE of the second conductive material and the first CTE.

Example D5 includes the electronic device of any of Examples D1-D4, wherein the inner region further includes a plurality of suspended particles in the second conductive material.

Example D6 includes the electronic device of Example D5, wherein the first conductive material has a first coefficient of thermal expansion (CTE), and wherein a number and material of the plurality of suspended particles is selected based on reducing a differential between a second CTE of the second conductive material and the first CTE.

Example D7 includes the electronic device of any of Examples D1-D4, wherein the inner region further includes a metallic core surrounded by the second conductive material.

Example D8 includes the electronic device of Example D7, wherein the first conductive material has a first coefficient of thermal expansion (CTE), and wherein a size and material of the metallic core is selected based on reducing a differential between a second CTE of the second conductive material and the first CTE.

Example D9 includes the electronic device of any of Examples D1-D8, further comprising a non-conductive liner arranged around each of the solder balls such that for each solder ball the non-conductive liner covers any exposed area of the solder ball.

Example D10 includes the electronic device of any of Examples D1-D9, further comprising a non-conductive underfill material arranged between each of the electronic components and the PCB such that the underfill covers any exposed area of each solder ball.

Example D11 includes the electronic device of any of Examples D1-D10, wherein the second conductive material is to flow into a crack in the outer layer.

Example MA1 includes a method of manufacturing a solder ball, comprising forming an outer layer comprising a first conductive material that is solid at an operating temperature of an electronic device, wherein the outer layer surrounds an inner region, introducing a hole into the outer layer, injecting a second conductive material through the hole of the outer layer into the inner region, wherein the second conductive material flows at the operating temperature of the electronic device, and sealing the hole of the outer layer such that the second conductive material is retained within the inner region.

Example MA2 includes the method of Example MA1, wherein the first conductive material comprises one or more of silver, tin, gold, copper, platinum, or bismuth.

Example MA3 includes the method of Example MA1 or MA2, wherein the second conductive material comprises one or more of indium or gallium.

Example MA4 includes the method of any of Examples MA1-MA3, wherein the first conductive material has a first coefficient of thermal expansion (CTE), and wherein the second conductive material is selected based on reducing a differential between a second CTE of the second conductive material and the first CTE.

Example MA5 includes the method of any of Examples MA1-MA4, wherein the inner region further includes a plurality of suspended particles in the second conductive material.

Example MA6 includes the method of Example MA5, wherein the first conductive material has a first coefficient of thermal expansion (CTE), and wherein a number and material of the plurality of suspended particles is selected based on reducing a differential between a second CTE of the second conductive material and the first CTE.

Example MA7 includes the method of any of Examples MA1-MA6, wherein the second conductive material is to flow into a crack in the outer layer.

Example MB1 includes a method of manufacturing a solder ball, comprising forming a conductive inner core as a solid material, disposing a second conductive material around the inner core, wherein the second conductive material flows at an operating temperature of an electronic device, bringing the second conductive material to a solid state, and disposing a third conductive material around the second conductive material to form an outer layer surrounding the second conductive material, wherein the third conductive material is solid at an operating temperature of the electronic device.

Example MB2 includes the method of Example MB1, wherein the third conductive material comprises one or more of silver, tin, gold, copper, platinum, or bismuth.

Example MB3 includes the method of Example MB1 or MB2, wherein the second conductive material comprises one or more of indium or gallium.

Example MB4 includes the method of any of Examples MB1-MB3, wherein the third conductive material has a first coefficient of thermal expansion (CTE), and wherein the second conductive material is selected based on reducing a differential between a second CTE of the second conductive material and the first CTE.

Example MB5 includes the method of any of Examples MB1-MB4, wherein the third conductive material has a first coefficient of thermal expansion (CTE), and wherein a size and material of the conductive inner core is selected based on reducing a differential between a second CTE of the second conductive material and the first CTE.

Example MB6 includes the method of any of Examples MB1-MB5, wherein the second conductive material is to flow into a crack in the outer layer.

Example MD1 includes a method of manufacturing an electronic device, comprising placing a plurality of solder balls, each at a respective contact point on a printed circuit board (PCB) of the electronic device, wherein each of the plurality of solder balls comprises an outer layer comprising a first conductive material that is solid at an operating temperature of the electronic device, and an inner region comprising a second conductive material that flows at the operating temperature of the electronic device, wherein the inner region is surrounded by the outer layer, placing a plurality of electronic components in position proximate to the PCB, wherein each electronic component is in contact with one or more of the solder balls, applying heat to the plurality of solder balls such that each outer layer melts in part to form an electrical bond with the respective contact point and with one of the electronic components, and allowing the outer layer of each solder ball to cool.

Example MD2 includes the method of Example MD1, wherein the first conductive material comprises one or more of silver, tin, gold, copper, platinum, or bismuth.

Example MD3 includes the method of Example MD1 or MD2, wherein the second conductive material comprises one or more of indium or gallium.

Example MD4 includes the method of any of Examples MD1-MD3, wherein the first conductive material has a first coefficient of thermal expansion (CTE), and wherein the second conductive material is selected based on reducing a differential between a second CTE of the second conductive material and the first CTE.

Example MD5 includes the method of any of Examples MD1-MD4, wherein the inner region further includes a plurality of suspended particles in the second conductive material.

Example MD6 includes the method of Example MD5, wherein the first conductive material has a first coefficient of thermal expansion (CTE), and wherein a number and material of the plurality of suspended particles is selected based on reducing a differential between a second CTE of the second conductive material and the first CTE.

Example MD7 includes the method of any of Examples MD1-MD4, wherein the inner region further includes a metallic core surrounded by the second conductive material.

Example MD8 includes the method of Example MD7, wherein the first conductive material has a first coefficient of thermal expansion (CTE), and wherein a size and material of the metallic core is selected based on reducing a differential between a second CTE of the second conductive material and the first CTE.

Example MD9 includes the method of any of Examples MD1-MD8, further comprising after allowing the outer layer of each solder ball to cool, applying an outer coating to each of the solder balls such that for each solder ball the outer coating covers any exposed area of the solder ball, wherein the outer coating comprises a non-conductive liner.

Example MD10 includes the method of any of Examples MD1-MD9, further comprising after allowing the outer layer of each solder ball to cool, applying a non-conductive underfill material between each of the electronic components and the PCB such that the underfill covers any exposed area of each solder ball.

Example MD11 includes the method of any of Examples MD1-MD10, wherein the second conductive material is to flow into a crack in the outer layer.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), solid state drive (SSD)/NAND drive controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections, including logical connections via intermediate components (e.g., device A may be coupled to device C via device B). In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A solder ball comprising:
an outer layer comprising a first conductive material that is solid at an operating temperature of an electronic device; and
an inner region comprising a second conductive material that flows at the operating temperature of the electronic device, wherein the inner region is surrounded by the outer layer.

2. The solder ball of claim 1, wherein the first conductive material comprises one or more of silver, tin, gold, copper, platinum, or bismuth.

3. The solder ball of claim 1, wherein the second conductive material comprises one or more of indium or gallium.

4. The solder ball of claim 1, wherein the first conductive material has a first coefficient of thermal expansion (CTE), and wherein the second conductive material is selected based on reducing a differential between a second CTE of the second conductive material and the first CTE.

5. The solder ball of claim 1, wherein the inner region further includes a plurality of suspended particles in the second conductive material.

6. The solder ball of claim 5, wherein the first conductive material has a first coefficient of thermal expansion (CTE), and wherein a number and material of the plurality of suspended particles is selected based on reducing a differential between a second CTE of the second conductive material and the first CTE.

7. The solder ball of claim 1, wherein the inner region further includes a metallic core surrounded by the second conductive material.

8. The solder ball of claim 7, wherein the first conductive material has a first coefficient of thermal expansion (CTE), and wherein a size and material of the metallic core is selected based on reducing a differential between a second CTE of the second conductive material and the first CTE.

9. The solder ball of claim 1, wherein the second conductive material is to flow into a crack in the outer layer.

10. A method of manufacturing a solder ball, comprising:
forming an outer layer comprising a first conductive material that is solid at an operating temperature of an electronic device, wherein the outer layer surrounds an inner region;
introducing a hole into the outer layer;
injecting a second conductive material through the hole of the outer layer into the inner region, wherein the second conductive material flows at the operating temperature of the electronic device; and
sealing the hole of the outer layer such that the second conductive material is retained within the inner region.

11. The method of claim 10, wherein the first conductive material comprises one or more of silver, tin, gold, copper, platinum, or bismuth.

12. The method of claim 10, wherein the second conductive material comprises one or more of indium or gallium.

13. The method of claim 10, wherein the first conductive material has a first coefficient of thermal expansion (CTE), and wherein the second conductive material is selected based on reducing a differential between a second CTE of the second conductive material and the first CTE.

14. The method of claim 10, wherein the inner region further includes a plurality of suspended particles in the second conductive material.

15. The method of claim 14, wherein the first conductive material has a first coefficient of thermal expansion (CTE), and wherein a number and material of the plurality of suspended particles is selected based on reducing a differential between a second CTE of the second conductive material and the first CTE.

16. The method of claim 10, wherein the second conductive material is to flow into a crack in the outer layer.

17. A method of manufacturing an electronic device, comprising:
placing a plurality of solder balls, each at a respective contact point on a printed circuit board (PCB) of the electronic device, wherein each of the plurality of solder balls comprises:
an outer layer comprising a first conductive material that is solid at an operating temperature of the electronic device, and
an inner region comprising a second conductive material that flows at the operating temperature of the electronic device,
wherein the inner region is surrounded by the outer layer;
placing a plurality of electronic components in position proximate to the PCB, wherein each electronic component is in contact with one or more of the solder balls,
applying heat to the plurality of solder balls such that each outer layer melts in part to form an electrical bond with the respective contact point and with one of the electronic components; and
allowing the outer layer of each solder ball to cool.

18. The method of claim 17, wherein the first conductive material comprises one or more of silver, tin, gold, copper, platinum, or bismuth, and wherein the second conductive material comprises one or more of indium or gallium.

19. The method of claim 17, further comprising after allowing the outer layer of each solder ball to cool, applying an outer coating to each of the solder balls such that for each solder ball the outer coating covers any exposed area of the solder ball, wherein the outer coating comprises a non-conductive liner.

20. The method of claim 17, further comprising after allowing the outer layer of each solder ball to cool, applying a non-conductive underfill material between each of the electronic components and the PCB such that the underfill covers any exposed area of each solder ball.
